(19) United States
(12) Patent Application Publication
(10) Pub. No.: US 2024/0405074 A1
(43) Pub. Date: Dec. 5, 2024

(54) SEMICONDUCTOR DEVICE

(71) Applicant: ROHM CO., LTD., Kyoto (JP)

(72) Inventor: Yuji KOGA, Kyoto (JP)

(73) Assignee: ROHM CO., LTD., Kyoto (JP)

(21) Appl. No.: 18/797,966

(22) Filed: Aug. 8, 2024

Related U.S. Application Data
(63) Continuation of application No. PCT/JP2023/001366, filed on Jan. 18, 2023.

(30) Foreign Application Priority Data
Mar. 10, 2022 (JP) 2022-037592

(51) Int. Cl. H01L 29/10; H01L 29/06; H01L 29/808

(52) U.S. Cl. CPC H01L 29/1066; H01L 29/0623; H01L 29/808

(57) ABSTRACT

A semiconductor device includes a semiconductor layer having a first surface and a second surface at an opposite side thereto, a bottom gate region of a first conductivity type that is formed in the semiconductor layer, and a top gate region of the first conductivity type that is formed in a surface layer portion of the first surface of the semiconductor layer and faces the bottom gate region in a thickness direction of the semiconductor layer, the bottom gate region includes a first bottom gate region at the source region side and a second bottom gate region at the drain region side, and an interval in the thickness direction between the second bottom gate region and the top gate region is greater than an interval in the thickness direction between the first bottom gate region and the top gate region.

### CROSS REFERENCE TO RELATED APPLICATIONS

The present application is a continuation application of PCT Application No. PCT/JP2023/001366, filed on Jan. 18, 2023, which corresponds to Japanese Patent Application No. 2022-37592 filed on Mar. 10, 2022, with the Japan Patent Office, and the entire disclosure of this application is incorporated herein by reference.

### TECHNICAL FIELD

The present disclosure relates to a semiconductor device.

### BACKGROUND ART

Japanese Patent Application Publication No. 2008-66619 discloses a junction field effect transistor. With the junction field effect transistor, an n⁻ type epitaxial layer is laminated on a semiconductor substrate. In the n⁻ type epitaxial layer, a plurality of gate regions are formed at intervals and, between mutually adjacent gate regions, a source region is formed at intervals from the gate regions. A gate electrode and a source electrode are connected to the gate regions and the source regions, respectively. A drain electrode is connected to a rear surface of the semiconductor substrate.

### BRIEF DESCRIPTION OF DRAWINGS

FIG. 1 is a schematic perspective view of a semiconductor device according to a preferred embodiment of the present disclosure.

FIG. 2 is a schematic plan view of a first element region of FIG. 1.

FIG. 3 is a sectional view taken along line III-III of FIG. 2.

FIG. 4 is a sectional view for describing the arrangement of an n-channel JFET according to a comparative example.

FIG. 5 is a diagram for describing an operation of the n-channel JFET of FIG. 4.

FIG. 6 is a diagram for describing the operation of the n-channel JFET of FIG. 4.

FIG. 7A is a simulation image showing an impact ionization in the n-channel JFET according to the comparative example when a drain-source voltage Vds is 30 V.

FIG. 7B is a simulation image showing an impact ionization in an n-channel JFET according to the preferred embodiment when the drain-source voltage Vds is 30 V.

FIG. 8 is a flowchart showing a portion of a manufacturing process of the semiconductor device.

FIG. 9 is a schematic plan view for describing a p-channel JFET according to a preferred embodiment of the present disclosure.

FIG. 10 is a sectional view taken along line X-X of FIG. 9.

FIG. 11 is a flowchart showing a portion of a manufacturing process of the JFET of FIG. 9.

### DESCRIPTION OF EMBODIMENTS

Next, preferred embodiments of the present disclosure shall be described in detail with reference to the attached drawings.

### [Overall Arrangement of Semiconductor Device 1]

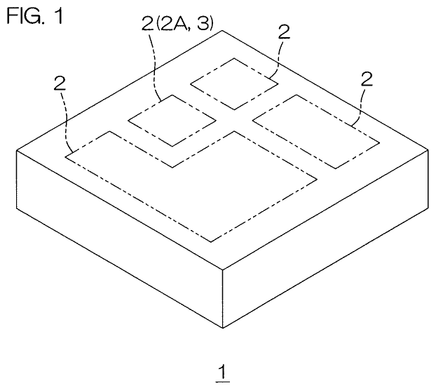

FIG. 1 is a schematic perspective view of a semiconductor device 1 according to a preferred embodiment of the present disclosure.

The semiconductor device 1 includes, for example, an integrated circuit (IC) device of chip shape. The semiconductor device 1 may be called an SSI (small scale IC), an MSI (middle scale IC), an LSI (large scale IC), a VLSI (very large scale IC), or an ULSI (ultra large scale IC) based on the number of circuit elements integrated.

The semiconductor device 1 has a plurality of element regions 2 in each of which a circuit element is formed. Each of the plurality of element regions 2 is a region in which a functional device is formed and is dielectrically isolated from other element regions. The functional device may include, for example, at least one among a semiconductor switching device, a semiconductor rectifying device, and a passive device. The functional device may include, for example, a circuit network in which at least two among a semiconductor switching device, a semiconductor rectifying device, and a passive device are combined.

The semiconductor switching device may include, for example, at least one among a MOSFET (metal oxide semiconductor field effect transistor), a BJT (bipolar junction transistor), an IGBT (insulated gate bipolar junction transistor), and a JFET (junction field effect transistor). The semiconductor rectifying device may include, for example, at least one among a pn junction diode, a pin junction diode, a Zener diode, a Schottky barrier diode, and a fast recovery diode. The passive device may include, for example, at least one among a resistor, a capacitor, and an inductor.

In this preferred embodiment, the plurality of element regions 2 include a first element region 2A. The first element region 2A may be an element region for JFET in which an n-channel JFET 3 is formed as the circuit element. Also, although four element regions 2 are shown in FIG. 1, the semiconductor device 1 have a larger number of element regions.

[Structure of n-Channel JFET 3]

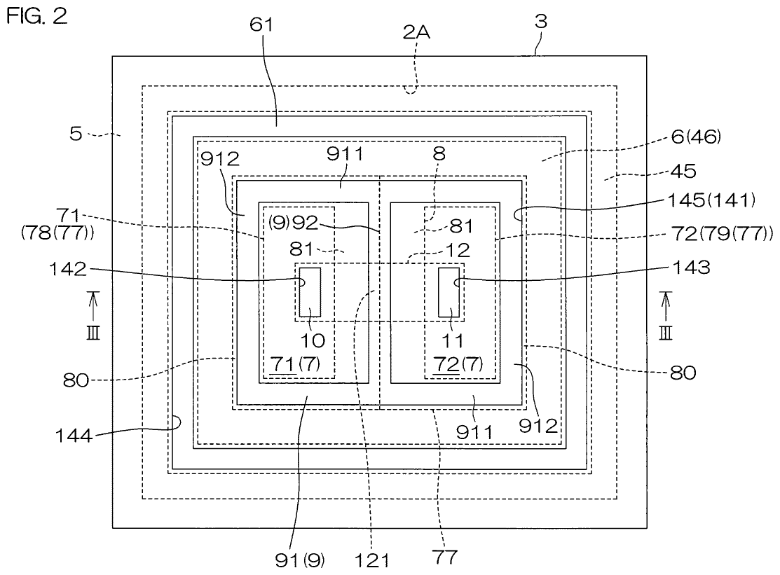

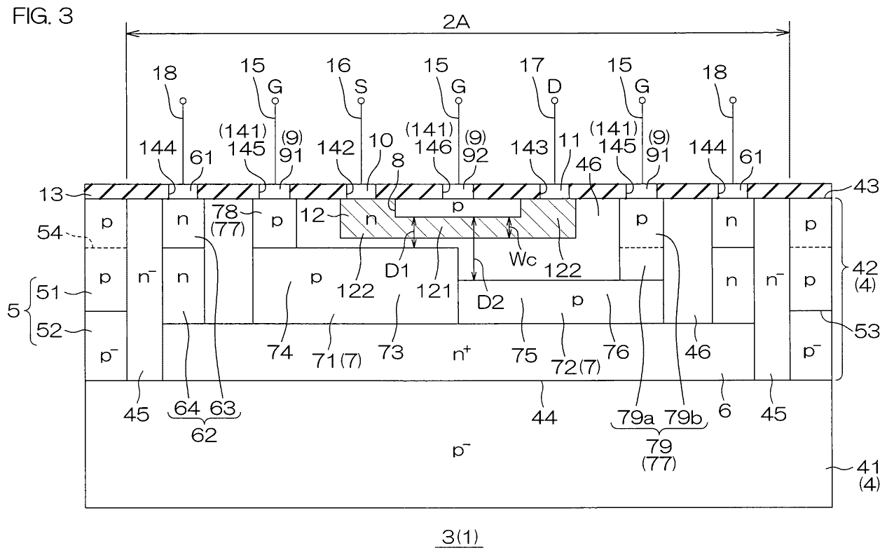

FIG. 2 is a schematic plan view of the first element region 2A (n-channel JFET 3) of FIG. 1. FIG. 3 is a sectional view taken along line III-III of FIG. 2.

The semiconductor device 1 (JFET 3) includes a semiconductor substrate 4, an element isolation portion 5, an embedded layer 6, a bottom gate region 7, a top gate region 8, a gate contact region 9, a source region 10, a drain region 11, a channel region 12, and a field insulating film 13. In FIG. 3, hatching is selectively applied to the channel region 12 to aid understanding of the structure.

The semiconductor substrate 4 may include a base substrate 41 and an epitaxial layer 42 as an example of a semiconductor layer.

Although the base substrate 41 is formed of a silicon (Si) substrate in this preferred embodiment, it may be a substrate formed of another material (for example, silicon carbide (SiC), etc.) instead. The base substrate 41 is of a p⁻ type in this preferred embodiment. The base substrate 41 may, for example, have an impurity concentration of not less than 1×10¹⁴ cm⁻³ and not more than 5×10¹⁸ cm⁻³. Also, a thickness of the base substrate 41 may, for example, be not less than 500 μm and not more than 800 μm before grinding.

The epitaxial layer 42 contacts the base substrate 41 and is laminated on the base substrate 41. The epitaxial layer 42 has an element principal surface 43 and a junction surface 44 facing an opposite side from the element principal surface 43 in a thickness direction of the epitaxial layer 42. The element principal surface 43 is a surface on which the element region 2 (the first element region 2A in FIG. 2 and FIG. 3) is formed. The junction surface 44 is a surface that contacts the base substrate 41. In this preferred embodiment, the epitaxial layer 42 has a conductivity type opposite that of the base substrate 41 and in this preferred embodiment, it is of an n⁻ type. The epitaxial layer 42 has an impurity concentration lower than that of the base substrate 41. The epitaxial layer 42 may, for example, have an impurity concentration of not less than 5×10¹⁴ cm⁻³ and not more than 1×10¹⁷ cm⁻³. Also, a thickness of the epitaxial layer 42 may, for example, be 3 μm to 20 μm.

The element isolation portion 5 may include an element isolation well. More specifically, as shown in FIG. 2 and FIG. 3, an element isolation well of a p type that is of a band shape that forms a closed curve in plan view may be formed such as to reach the base substrate 41 from the element principal surface 43 of the epitaxial layer 42. Although in this preferred embodiment, the element isolation portion 5 is formed in a quadrilateral annular shape in plan view as shown in FIG. 2, it may be of another closed curve structure, for example, of circular annular shape, triangular annular shape, etc., instead.

Referring to FIG. 3, the element isolation portion 5 may be constituted of a two-layer structure of a well region 51 of p type disposed at an upper side and a low isolation (L/I) region 52 of p⁻ type disposed at a lower side. An impurity concentration of the low isolation region 52 may be lower than that of the well region 51. A boundary 53 between the regions 51 and 52 may be set in a thickness direction intermediate portion of the epitaxial layer 42. For example, the boundary 53 between the regions 51 and 52 may be set at a depth position of 1.0 μm to 2.0 μm from the element principal surface 43 of the epitaxial layer 42. The first element region 2A constituted of a portion of the epitaxial layer 42 surrounded by the element isolation portion 5 on the base substrate 41 is thereby demarcated in the semiconductor substrate 4.

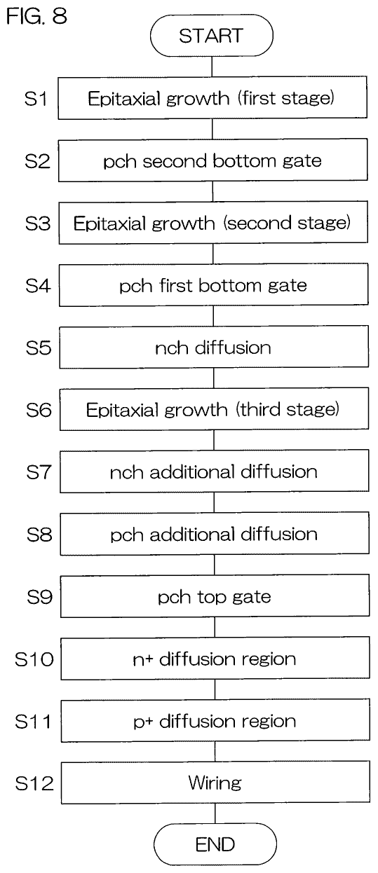

Here, in FIG. 3, a virtual boundary 54 is indicated at an intermediate portion of the well region 51 in the thickness direction of the epitaxial layer 42. The virtual boundary 54 does not indicate a boundary that partitions the well region 51 physically and functionally into a plurality of regions but indicates, for example, a depth position corresponding to a timing at which a process is switched during manufacture of the semiconductor device 1. For example, as shown in FIG. 8 (described below), in a case where the epitaxial layer 42 is grown dividedly in three stages, the virtual boundary 54 may indicate a depth position corresponding to a switching timing between an epitaxial process of a second stage and an epitaxial process of a third stage.

The embedded layer 6 (B/L) of an n⁺ type is formed in an island shape in plan view as shown in FIG. 2. The embedded layer 6 is surrounded by an outer epitaxial region 45 of the n⁻ type of the epitaxial layer 42. The outer epitaxial region 45 is a region in which the impurity concentration of the epitaxial layer 42 is maintained. On the other hand, an impurity region such as the embedded layer 6, etc., that is formed by diffusing an impurity separately in the epitaxial layer 42 may be referred to as a diffusion region in contrast to an epitaxial region.

Although in this preferred embodiment, the embedded layer 6 is formed in a quadrilateral shape in plan view as shown in FIG. 2, it may be of another planar structure, for example, of circular shape, triangular shape, etc., instead. Also, the embedded layer 6 is selectively embedded in the first element region 2A as shown in FIG. 3. The embedded layer 6 is formed at a boundary portion between the base substrate 41 and the epitaxial layer 42 in the semiconductor substrate 4. The embedded layer 6 may extend across the boundary between the base substrate 41 and the epitaxial layer 42 and a portion may be embedded in the base substrate 41. A thickness of the embedded layer 6 may, for example, be 1.0 μm to 6.0 μm.

A first contact region 61 and a first intermediate region 62 for the embedded layer 6 are also formed in the epitaxial layer 42.

In this preferred embodiment, the first contact region 61 is of the n⁺ type and has a higher impurity concentration than the embedded layer 6. As shown in FIG. 2 and FIG. 3, the first contact region 61 is formed in a surface layer portion of the element principal surface 43 of the epitaxial layer 42 and is of an annular shape (a quadrilateral annular shape in this preferred embodiment) along a peripheral edge portion of the embedded layer 6 in plan view.

The first intermediate region 62 may be constituted of a two-layer structure of an upper intermediate region 63 of the n type that is disposed at an upper side and a lower intermediate region 64 of the n type that is disposed at a lower side. An impurity concentration of the lower intermediate region 64 may be lower than that of the upper intermediate region 63. Thereby, an inner epitaxial region 46 that is constituted of a portion of the epitaxial layer 42 surrounded by the embedded layer 6, the first contact region 61, and the first intermediate region 62 is formed in the epitaxial layer 42 as shown in FIG. 3. As with the outer epitaxial region 45, the inner epitaxial region 46 is a region in which the impurity concentration of the epitaxial layer 42 is maintained.

The bottom gate region 7 is formed in an island shape in plan view as shown in FIG. 2. Although in this preferred embodiment, the bottom gate region 7 is formed in a quadrilateral shape in plan view as shown in FIG. 2, it may be of another planar structure, for example, of circular shape, triangular shape, etc., instead.

Referring to FIG. 3, the bottom gate region 7 is formed separated to the junction surface 44 side from the element principal surface 43 of the epitaxial layer 42. The bottom gate region 7 may be embedded in the epitaxial layer 42. The inner epitaxial region 46 is formed in a periphery of the bottom gate region 7. In this preferred embodiment, the bottom gate region 7 is surrounded by the inner epitaxial region 46 in a state where its bottom portion contacts the embedded layer 6 in the thickness direction of the epitaxial layer 42. Here, the bottom gate region 7 may be surrounded by the inner epitaxial region 46 in a state of being separated upward from the embedded layer 6 in the thickness direction of the epitaxial layer 42 instead. The bottom gate region 7 is of the p type in this preferred embodiment.

The top gate region 8 is formed in a rectilinear shape in plan view as shown in FIG. 2. In this preferred embodiment, the top gate region 8 extends in a direction of segmenting the bottom gate region 7 of island shape as shown in FIG. 2. The bottom gate region 7 has a first bottom gate region 71 and a second bottom gate region 72 that are divided by the top gate region 8 in plan view. That is, the bottom gate region 7 has the first bottom gate region 71 at the source region 10 side and the second bottom gate region 72 at the drain region 11 side.

Referring to FIG. 3, the top gate region 8 is formed in a surface layer portion of the element principal surface 43 of the epitaxial layer 42. The top gate region 8 faces the bottom gate region 7 in the thickness direction of the epitaxial layer 42. In this preferred embodiment, the top gate region 8 is of the p type. An impurity concentration of the top gate region 8 may be the same as the impurity concentration of the bottom gate region 7.

Referring to FIG. 3, a thickness (depth of impurity diffusion) of the first bottom gate region 71 at the source region 10 side and a thickness (depth of impurity diffusion) of the second bottom gate region 72 at the drain region 11 side differ. The thickness of the second bottom gate region 72 is thinner than the thickness of the first bottom gate region 71.

Thereby, an interval D1 in the thickness direction between the top gate region 8 and the first bottom gate region 71 is smaller than an interval D2 in the thickness direction between the top gate region 8 and the second bottom gate region 72. In other words, the interval D2 is greater than the interval D1. The interval D1 is preferably not less than ⅕ and not more than ⅘ of the interval D2. In this preferred embodiment, the interval D1 is approximately ½ of the interval D2.

The first bottom gate region 71 may integrally include a first gate facing portion 73 and a first gate lead-out portion 74. The first gate facing portion 73 may be a region that faces a region of the top gate region 8 at the source region 10 side in the thickness direction of the epitaxial layer 42. The first gate lead-out portion 74 is led out to the source region 10 side in a direction along the element principal surface 43 from the first gate facing portion 73. The first gate lead-out portion 74 does not face the top gate region 8 in the thickness direction of the epitaxial layer 42 and may thus be referred to as a first gate non-facing portion.

The second bottom gate region 72 may integrally include a second gate facing portion 75 and a second gate lead-out portion 76. The second gate facing portion 75 may be a region that faces a region of the top gate region 8 at the drain region 11 side in the thickness direction of the epitaxial layer 42. The second gate lead-out portion 76 is led out to the drain region 11 side in the direction along the element principal surface 43 from the second gate facing portion 75. The second gate lead-out portion 76 does not face the top gate region 8 in the thickness direction of the epitaxial layer 42 and may thus be referred to as a second gate non-facing portion.

In this preferred embodiment, the gate contact region 9 is of a p⁺ type and has a higher impurity concentration than the bottom gate region 7 and the top gate region 8. As shown in FIG. 2 and FIG. 3, the gate contact region 9 is formed in a surface layer portion of the element principal surface 43 of the epitaxial layer 42.

The gate contact region 9 integrally includes a first contact portion 91 that is electrically connected to the bottom gate region 7 and a second contact portion 92 that is electrically connected to the top gate region 8.

Referring to FIG. 2, the first contact portion 91 is formed in an annular shape along a peripheral edge portion of the bottom gate region 7. In this preferred embodiment, the first contact portion 91 is formed in a quadrilateral annular shape in plan view that includes a pair of first rectilinear portions 911 that face each other and a pair of second rectilinear portions 912 that face each other. The first rectilinear portions 911 and the second rectilinear portions 912 may be orthogonal to each other.

Referring to FIG. 3, a gate intermediate region 77 is formed between the first contact portion 91 and a peripheral edge portion (the first gate lead-out portion 74 and the second gate lead-out portion 76) of the bottom gate region 7. In this preferred embodiment, the gate intermediate region 77 is of the p type and has a lower impurity concentration than the bottom gate region 7 and the top gate region 8.

The gate intermediate region 77 includes a first gate intermediate region 78 that is formed between the first contact portion 91 and the first gate lead-out portion 74 and a second gate intermediate region 79 that is formed between the first contact portion 91 and the second gate lead-out portion 76. The second gate intermediate region 79 includes a lower region 79a and an upper region 79b. A length of the second gate intermediate region 79 along the thickness direction of the epitaxial layer 42 is longer than a length of the first gate intermediate region 78 along the thickness direction of the epitaxial layer 42.

The first gate intermediate region 78 is physically and electrically connected to both the first contact portion 91 and the first gate lead-out portion 74 and is sandwiched from above and below by the first contact portion 91 and the first gate lead-out portion 74. The second gate intermediate region 79 is physically and electrically connected to both the first contact portion 91 and the second gate lead-out portion 76 and is sandwiched from above and below by the first contact portion 91 and the second gate lead-out portion 76. The first contact portion 91 (gate contact region 9) is thereby electrically connected to the bottom gate region 7 via the gate intermediate regions 78 and 79.

Also, with reference to FIG. 2, the gate intermediate region 77 is formed in an annular shape (quadrilateral annular shape in this preferred embodiment) along the first contact portion 91. The gate intermediate region 77 has a wider width than the first contact portion 91 in plan view. Thereby, the gate intermediate region 77 has a lead-out portion 80 led out from both sides in a width direction of the first contact portion 91. In this preferred embodiment, the gate intermediate region 77 of annular shape has the lead-out portion 80 at both an inner side and an outer side of the annulus.

With reference to FIG. 2, the second contact portion 92 is formed across a plurality of locations of the first contact portion 91 such as to segment the bottom gate region 7. In this preferred embodiment, the second contact portion 92 is formed in a rectilinear shape that connects the pair of first rectilinear portions 911 to each other. The second contact portion 92 is formed on the top gate region 8 and is of the rectilinear shape along the top gate region 8. Therefore, in plan view, the first bottom gate region 71 and the second bottom gate region 72 may be divided from each other in a lateral direction by the second contact portion 92. In this preferred embodiment, the second contact portion 92 is present at a position directly above a boundary between the first bottom gate region 71 and the second bottom gate region 72.

Here, the boundary between the first bottom gate region 71 and the second bottom gate region 72 may, in plan view, be disposed further to the drain region 11 side than a width center of the top gate region 8 (width center of the second contact portion 92) within a range from the width center of the top gate region 8 to an end of the top gate region 8 at the drain region 11 side. Also, the boundary between the first bottom gate region 71 and the second bottom gate region 72 may, in plan view, be disposed further to the source region 10 side than the width center of the top gate region 8 (width center of the second contact portion 92) within a range from the width center of the top gate region 8 to an end of the top gate region 8 at the source region 10 side.

Here, the top gate region 8 has a wider width than the second contact portion 92 in plan view. Thereby, the top gate region 8 has a lead-out portion 81 led out from both sides in a width direction of the second contact portion 92. The second contact portion 92 is physically and electrically connected to the top gate region 8. Thereby, the gate contact region 9 including the first contact portion 91 and the second contact portion 92 is electrically connected in common to the bottom gate region 7 and the top gate region 8.

In this preferred embodiment, the source region 10 is of the n⁺ type and has a higher impurity concentration than the embedded layer 6. As shown in FIG. 2 and FIG. 3, the source region 10 is formed in a surface layer portion of the element principal surface 43 of the epitaxial layer 42. Referring to FIG. 2, the source region 10 is formed on the first bottom gate region 71 and is separated from the top gate region 8 in the direction along the element principal surface 43.

The source region 10 is formed near a central portion of the first bottom gate region 71 in a direction orthogonal to the top gate region 8 (right-left direction of the sheet of FIG. 3). The source region 10 may instead be formed to a side closer to the top gate region 8 or a side further from the top gate region 8 than the central portion of the first bottom gate region 71 in the direction orthogonal to the top gate region 8.

In this preferred embodiment, the drain region 11 is of the n⁺ type and has a higher impurity concentration than the embedded layer 6. As shown in FIG. 2 and FIG. 3, the drain region 11 is formed in a surface layer portion of the element principal surface 43 of the epitaxial layer 42. Referring to FIG. 2, the drain region 11 is formed on the second bottom gate region 72 and is separated to an opposite side of the source region 10 from the top gate region 8 in the direction along the element principal surface 43.

The drain region 11 is formed near a central portion of the second bottom gate region 72 in the direction orthogonal to the top gate region 8. The drain region 11 may instead be formed to a side closer to the top gate region 8 or a side further from the top gate region 8 than the central portion of the second bottom gate region 72 in the direction orthogonal to the top gate region 8.

Referring to FIG. 2, the channel region 12 is formed between the source region 10 and the drain region 11 in the direction along the element principal surface 43. For example, the channel region 12 may be formed at a substantially central portion between the source region 10 and the drain region 11. Referring to FIG. 3, the channel region 12 is formed between the bottom gate region 7 and the top gate region 8 in the thickness direction of the epitaxial layer 42. In this preferred embodiment, the channel region 12 is of the n type. A width Wc of the channel region 12 in the thickness direction of the epitaxial layer 42 may, for example, be not less than 0.5 μm and not more than 2 μm.

In this preferred embodiment, the channel region 12 contacts the top gate region 8 and forms an interface with the top gate region 8. On the other hand, the channel region 12 is separated from the bottom gate region 7. That is, a portion of the inner epitaxial region 46 of the n-type is interposed between the channel region 12 and the bottom gate region 7. Thereby, a pnp structure with which portions of the channel region 12 of the n type and the inner epitaxial region 46 of the n⁻ type are sandwiched from both upper and lower sides by the p type gate regions 7 and 8 is formed. This pnp structure forms an n channel junction field effect transistor (JFET 3).

Here, the channel region 12 may contact both the bottom gate region 7 and the top gate region 8. Also, the channel region 12 may contact the bottom gate region 7 and be separated from the top gate region 8.

In this preferred embodiment, the channel region 12 may include a channel portion 121 and a channel peripheral portion 122. The channel portion 121 is a portion that is sandwiched between the top gate region 8 and the inner epitaxial region 46 below the top gate region 8. The channel peripheral portion 122 is formed further outward than the top gate region 8 in plan view and may be a portion that surrounds both the top gate region 8 and the channel portion 121.

A field insulating film 13 is formed on the element principal surface 43 of the epitaxial layer 42. The field insulating film 13 may, for example, be a LOCOS film (silicon oxide film) that is formed by selectively oxidizing the element principal surface 43. The field insulating film 13 has a gate opening 141 that exposes the gate contact region 9, a source opening 142 that exposes the source region 10, a drain opening 143 that exposes the drain region 11, and a first contact opening 144 that exposes the first contact region 61.

The gate opening 141 has the same planar shape as the gate contact region 9. The gate opening 141 includes a first opening 145 that exposes the first contact portion 91 and a second opening 146 that exposes the second contact portion 92. The first opening 145 is formed in an annular shape along the first contact portion 91 of annular shape. The second opening 146 is formed across a plurality of locations of the first opening 145 such as to segment the bottom gate region 7.

The source opening 142 has the same planar shape as the source region 10. The drain opening 143 has the same planar shape as the drain region 11.

The first contact opening 144 has the same planar shape as the first contact region 61. The first contact opening 144 is formed in an annular shape along the first contact region 61 of annular shape.

Wirings are connected to the impurity regions exposed from the openings 141 to 146. For example, a gate wiring 15 may be connected to the gate contact region 9, a source wiring 16 may be connected to the source region 10, a drain wiring 17 may be connected to the drain region 11, and a first wiring 18 may be connected to the first contact region 61.

### Effects of the Preferred Embodiment

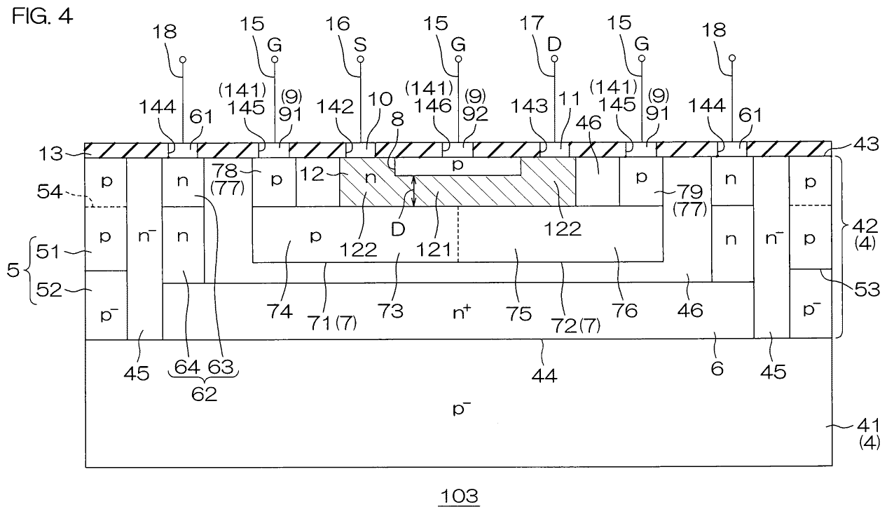

FIG. 4 is a sectional view for describing the arrangement of an n-channel JFET 103 according to a comparative example and is a sectional view corresponding to the sectional view of FIG. 3. In FIG. 4, portions corresponding to respective portions in FIG. 3 are indicated with the same reference signs attached as in FIG. 3.

The JFET 103 according to the comparative example differs in the following points (a), (b), and (c) in comparison to the JFET 3 of the preferred embodiment.
(a) The thickness of the bottom gate region 7 is the same over the entirety. In other words, the thickness of the first bottom gate region 71 and the thickness of the second bottom gate region 72 are the same. However, an interval D between the bottom gate region 7 and the top gate region 8 is equal to the interval D1 between the first bottom gate region 71 and the top gate region 8 in the JFET 3 of the preferred embodiment.
(b) The channel region 12 contacts the bottom gate region 7.
(c) The bottom gate region 7 is separated from the embedded layer 6. However, the bottom gate region 7 may contact the embedded layer 6.

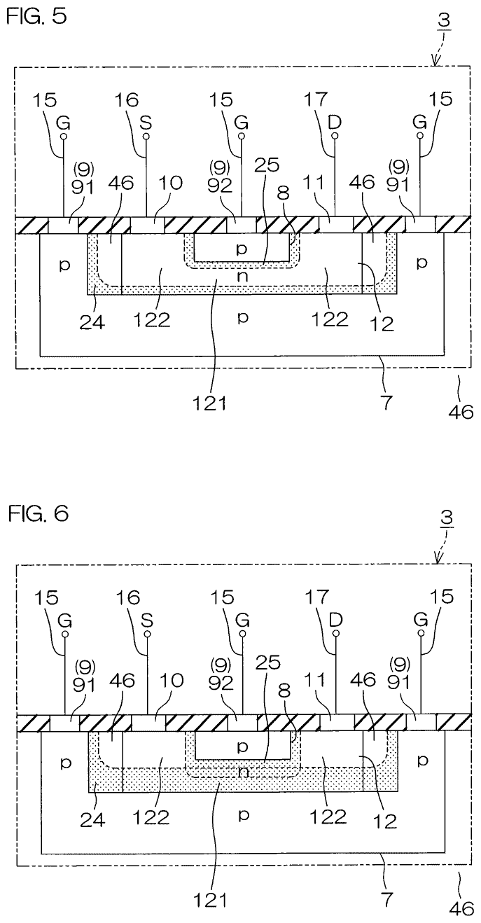

FIG. 5 and FIG. 6 are diagrams for describing an operation of the JFET 103. FIG. 5 shows an on state of the JFET 103 and FIG. 6 shows an off state of the JFET 103. Next, the operation of the JFET 103 shall be described. When a voltage is applied with the drain wiring 17 being a high potential side and the source wiring 16 being a low potential side, conduction is achieved between the source region 10 and the drain region 11 via the channel region 12. If at this point, a control voltage (gate voltage) is not applied or a control voltage (gate voltage) of a negative side with respect to the source potential and of a degree such that the channel region is not interrupted by depletion layers 24 and 25 is applied to the gate wiring 15, the depletion layers 24 and 25 having sufficient spread from a pn junction between the n type channel region 12 and the p type bottom gate region 7 and a pn junction between the n type channel region 12 and the p type top gate region 8 do not extend (see FIG. 5). That is a current flowing through the channel region 12 in the direction along the element principal surface 43 is not interrupted by the depletion layers 24 and 25 and the JFET 103 is in an on state (normally on). On the other hand, when the gate voltage that is of the negative side with respect to the source potential and is not less than that by which the depletion layers 24 and 25 spread fully inside the channel region 12 is applied to the gate wiring 15, it becomes difficult for electrons to flow inside the channel region 12 and consequently, the flow of electrons in the channel region 12 is interrupted by the depletion layers 24 and 25 (see FIG. 6). That is, the JFET 103 is put in an off state. The gate voltage in this state is defined as an interruption voltage.

Even if a demand value of the interruption voltage is close to 1 V, in the JFET 103 in which a voltage of several tens of volts is applied between the drain and source, the channel region 12 at the drain region 11 side is pinched off under a conditions of voltage where a drain-source voltage Vds is not less than 1 V and a source-gate voltage Vgs is 0 V. If in this state, the drain-source s further, a field strength in a voltage Vds vicinity of the drain region 11 increases. An impact ionization phenomenon (ionization by collision) then occurs due to electrons moving from the source region 10 side to the drain region 11 side and electron-hole pairs are formed. Charges (holes) formed in this process flow into the gate regions 7 and 8 and a gate current increases.

With the JFET 3 according to the preferred embodiment, the interval D2 in the thickness direction between the second bottom gate region 72 at the drain region side and the top gate region 8 is set greater than the interval D1 in the thickness direction between the first bottom gate region 71 at the source region side and the top gate region 8. Since occurrence of the impact ionization phenomenon can thereby be suppressed, the gate current can be reduced. The reason for this shall be described below.

An interruption voltage of the JFET 3 is determined by the spread of depletion layers at the source region side. That is, the narrower the interval D1, the less the interruption voltage. The field strength when a high voltage is applied between the drain and source is determined by the spread of the depletion layers at the drain region side. That is, the greater the interval D2, the weaker the field strength.

In the preferred embodiment, the depth of impurity diffusion differs between the first bottom gate region 71 at which the interruption voltage is determined and the second bottom gate region 72 at which the field strength at the high drain-source voltage is determined. Specifically, the interval D2 is made greater than the interval D1 by making the depth of impurity diffusion of the second bottom gate region 72 thinner than the depth of impurity diffusion of the first bottom gate region 71. Since the field strength can thereby be suppressed while keeping low the interruption voltage, the occurrence of the impact ionization phenomenon can be suppressed. The gate current can thereby be reduced.

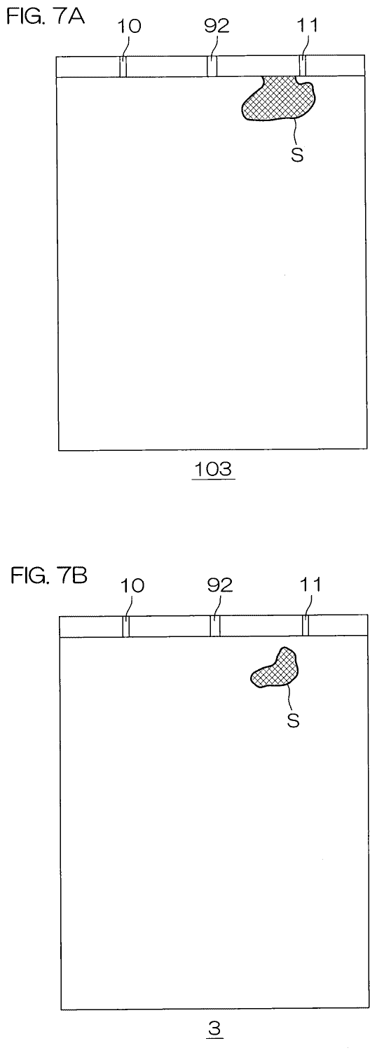

FIG. 7A is a simulation image showing an impact ionization in the n-channel JFET 103 according to the comparative example when the drain-source voltage Vds is 30 V. FIG. 7B is a simulation image showing an impact ionization in the n-channel JFET 3 according to the preferred embodiment when the drain-source voltage Vds is 30 V.

A region S indicated by hatching in each of FIG. 7A and FIG. 7B shows a region in which an impact ionization of a predetermined level or more is occurring. From FIG. 7A and FIG. 7B, it can be understood that in the preferred embodiment, the impact ionization in the vicinity of the drain region 11 when the drain-source voltage Vds is high is suppressed in comparison to the comparative example.

When the drain-source voltage is 15 V, whereas the gate current in the comparative example is 1.0×10⁻⁹ [A], that in the preferred embodiment is reduced to 1.0×10⁻¹⁰ [A]. Also, when the drain-source voltage is 20 V, whereas the gate current in the comparative example is 1.0×10⁻⁸ [A], that in the preferred embodiment is reduced to 1.0×10⁻¹⁰ [A]. Also, when the drain-source voltage is 25 V, whereas the gate current in the comparative example is 1.0×10⁻⁷ [A], that in the preferred embodiment is reduced to 1.0×10⁻¹⁰ [A]. Also, when the drain-source voltage is 30 V, whereas the gate current in the comparative example is 1.0×10⁻⁶ [A], that in the preferred embodiment is reduced to 1.0×10⁻⁹ [A].

Also, with the present embodiment, a drain current with respect to the drain-source voltage can be increased because a cross-sectional area of a transfer pathway for electrons is increased at the second bottom gate region 72 side in comparison to the comparative example.

When the drain-source voltage is 5 V, whereas the drain current in the comparative example is 4×10⁻⁴ [A], that in the preferred embodiment is increased to 1.4×10⁻³ [A]. Also, when the drain-source voltage is 15 V, whereas the drain current in the comparative example is 5.0×10⁻⁴ [A], that in the preferred embodiment is increased to 1.6×10⁻³ [A]. Also, when the drain-source voltage is 25 V, whereas the drain current in the comparative example is 5×10⁻⁴ [A], that in the preferred embodiment is increased to 1.7×10⁻³ [A].

### [Method for Manufacturing the Semiconductor Device 1]

FIG. 8 is a flowchart showing a portion of a manufacturing process of the semiconductor device 1. Next, an example of the manufacturing process of the semiconductor device 1 shall be described with reference to FIG. 8.

To manufacture the semiconductor device 1, first, the base substrate 41 of the p⁻ type is prepared. Next, an impurity of the n type and an impurity of the p type are implanted selectively into a front surface of the base substrate 41. Then while adding the impurity of the n type, the silicon of the base substrate 41 is grown epitaxially (step S1). The semiconductor substrate 4 that includes the base substrate 41 of the p⁻ type and the epitaxial layer 42 (first stage portion) of the n⁻ type is thereby formed.

The impurity of the n type and the impurity of the p type that are implanted into the base substrate 41 during the epitaxial growth of the base substrate 41 diffuse in a growth direction of the epitaxial layer 42. The embedded layer 6 and the low isolation region 52 of the p-type are thereby formed at the boundary portion between the base substrate 41 and the epitaxial layer 42.

Next, an ion implantation mask having an opening selectively in a region in which the second bottom gate region 72 of the p type is to be formed is formed on the epitaxial layer 42. The impurity of the p type is then implanted into the e epitaxial layer 42 via the ion implantation mask. The second bottom gate region 72 of the p type is thereby formed (step S2).

The silicon of the base substrate 41 is then grown epitaxially further while adding the impurity of the n type (step S3). A second stage portion of the epitaxial layer 42 of the n⁻ type is thereby formed.

Next, an ion implantation mask having openings selectively in regions in which the first bottom gate region 71 of the p type, the second gate intermediate region 79 of the p type, and the well region 51 of the p type are to be formed is formed on the epitaxial layer 42. The impurity of the p type is then implanted into the epitaxial layer 42 via the ion implantation mask. Thereby, the first bottom gate region 71 of the p type is formed and the lower region 79a of the second gate intermediate region 79 is formed. Also, the element isolation portion 5 (element isolation well) constituted of the two-layer structure of the well region 51 (the portion lower than the virtual boundary 54 of FIG. 3) of the p type and the low isolation region 52 of the p⁻ type is formed (step S4).

Next, an ion implantation mask having an opening selectively in a region in which the lower intermediate region 64 of the n type is to be formed is formed on the epitaxial layer 42. The impurity of the n type is then implanted into the epitaxial layer 42 via the ion implantation mask. Thereby, the lower intermediate region 64 of the n type is formed (step S5). The silicon of the base substrate 41 is then grown epitaxially further while adding the impurity of the n type (step S6). A third stage portion of the epitaxial layer 42 of the n⁻ type is thereby formed.

Next, an ion implantation mask having an opening selectively in a region in which the upper intermediate region 63 of the n type is to be formed is formed on the epitaxial layer 42. The impurity of the n type is then implanted into the epitaxial layer 42 via the ion implantation mask. Thereby, the upper intermediate region 63 of the n type is formed.

Next, an ion implantation mask having an opening selectively in a region in which the channel region 12 of the n type is to be formed is formed on the epitaxial layer 42. The impurity of the n type is then implanted into the epitaxial layer 42 via the ion implantation mask. Thereby, the channel region 12 of the n type is formed (step S7).

Next, an ion implantation mask having openings selectively in regions in which the well region 51 of the p type and the gate intermediate region 77 of the p type are to be formed is formed on the epitaxial layer 42. The impurity of the p type is then implanted into the epitaxial layer 42 via the ion implantation mask. Thereby, the well region 51 (the portion higher than the virtual boundary 54 of FIG. 3) of the p type, the first gate intermediate region 78 of the p type, and the upper region 79b of the second gate intermediate region 79 are formed. Thereby, the gate intermediate region 77 constituted of the first gate intermediate region 78 and the second gate intermediate region 79 is formed (step S8).

Next, an ion implantation mask having an opening selectively in a region in which the top gate region 8 of the p type is to be formed is formed on the epitaxial layer 42. The impurity of the p type is then implanted into the epitaxial layer 42 via the ion implantation mask. Thereby, the top gate region 8 of the p type is formed (step S9).

Next, an ion implantation mask having openings selectively in regions in which the source region 10 of the n⁺ type, the drain region 11 of the n′ type, and the first contact region 61 of the n⁺ type are to be formed is formed on the epitaxial layer 42. The impurity of the n type is then implanted into the epitaxial layer 42 via the ion implantation mask. Thereby, the source region 10 of the n⁺ type, the drain region 11 of the n⁺ type, and the first contact region 61 of the n⁺ type are formed (step S10).

Next, an ion implantation mask having an opening selectively in a region in which the gate contact region 9 of the p⁺ type is to be formed is formed on the epitaxial layer 42. The impurity of the p type is then implanted into the epitaxial layer 42 via the ion implantation mask. Thereby, the gate contact region 9 of the p⁺ type is formed (step S11).

Next, by a forming step of the wirings 15 to 18 (step S12), etc., being performed, the semiconductor device 1 described above is obtained.

Here, the manufacturing process of the semiconductor device 1 described using FIG. 8 is one example and the semiconductor device 1 may be manufactured by another manufacturing process instead.

[Structure of p-Channel JFET 3A]

Although with the preferred embodiment described above, the semiconductor device 1 in which the n-channel JFET 3 is formed in the first element region 2A was described, a p-channel JFET 3A may be formed in the first element region 2A instead.

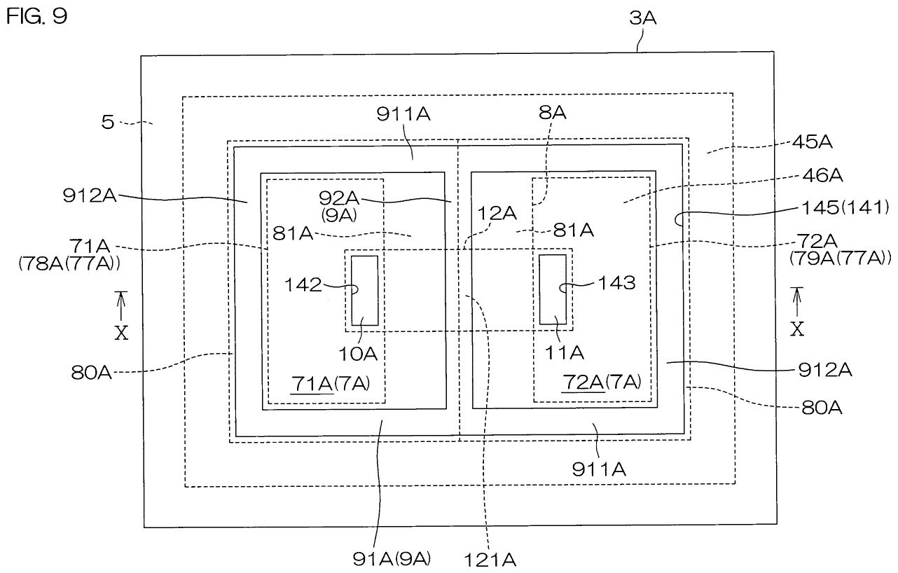

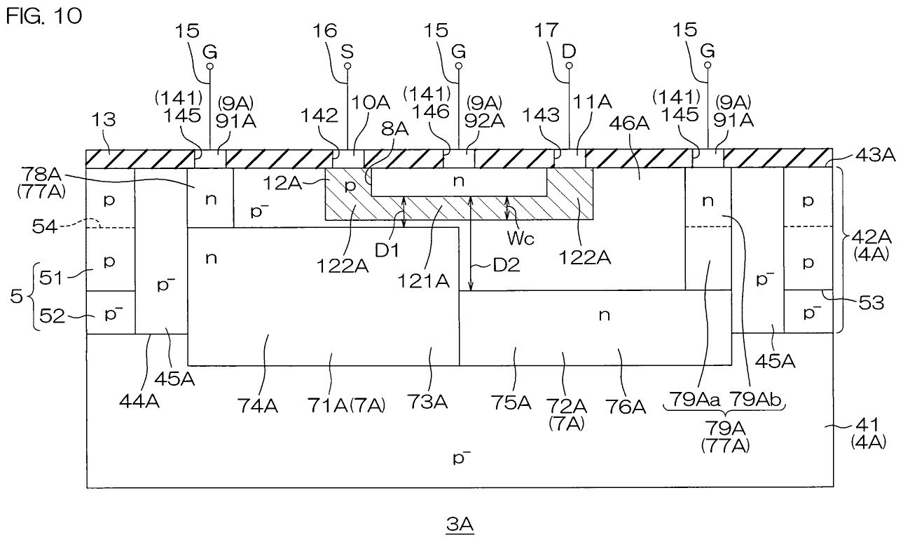

FIG. 9 is a schematic plan view of the p-channel JFET 3A. FIG. 10 is a sectional view taken along line X-X of FIG. 9. In regard to elements in FIG. 9 and FIG. 10 that are the same as elements shown in FIG. 2 and FIG. 3 described above, the same reference numbers as in FIG. 2 and FIG. 3 shall be attached to the elements and description thereof shall be omitted.

As arrangements differing from those of the JFET 3 described above, the JFET 3A includes a semiconductor substrate 4A, a bottom gate region 7A, a top gate region 8A, a gate contact region 9A, a source region 10A, a drain region 11A, a channel region 12A, an epitaxial layer 42A, and a gate intermediate region 77A. In FIG. 10, hatching is selectively applied to the channel region 12A to aid understanding of the structure.

In this preferred embodiment, the epitaxial layer 42A is of the p⁻ type. The epitaxial layer 42A contacts the base substrate 41 and is laminated on the base substrate 41. The epitaxial layer 42A has an element principal surface 43A and a junction surface 44A facing an opposite side from the element principal surface 43A in a thickness direction of the epitaxial layer 42A. Also, the epitaxial layer 42A includes an outer epitaxial region 45A and an inner epitaxial region 46A. In this preferred embodiment, the embedded layer 6 of FIG. 3 is not formed. Still, even in this preferred embodiment, the embedded layer 6 such as shown in FIG. 3 may be formed.

The bottom gate region 7A is formed in an island shape in plan view as shown in FIG. 9. Although in this preferred embodiment, the bottom gate region 7A is formed in a quadrilateral shape in plan view as shown in FIG. 9, it may be of another planar structure, for example, of circular shape, triangular shape, etc., instead.

Referring to FIG. 10, the bottom gate region 7A is formed separated to the junction surface 44A side from the element principal surface 43A of the epitaxial layer 42A. The bottom gate region 7A may be embedded in the epitaxial layer 42A. In this preferred embodiment, the bottom gate region 7A extends across a boundary between the base substrate 41 and the epitaxial layer 42A and a portion thereof is embedded in the base substrate 41. The bottom gate region 7A is of the n type in this preferred embodiment.

The top gate region 8A is formed in a rectilinear shape in plan view as shown in FIG. 9. In this preferred embodiment, the top gate region 8A extends in a direction of segmenting the bottom gate region 7A of island shape as shown in FIG. 9. The bottom gate region 7A has a first bottom gate region 71A and a second bottom gate region 72A that are divided by the top gate region 8A in plan view. That is, the bottom gate region 7A has the first bottom gate region 71A at the source region 10A side and the second bottom gate region 72A at the drain region 11A side.

Referring to FIG. 10, the top gate region 8A is formed in a surface layer portion of the element principal surface 43A of the epitaxial layer 42A. The top gate region 8A faces the bottom gate region 7A in the thickness direction of the epitaxial layer 42A. In this preferred embodiment, the top gate region 8A is of the n type. An impurity concentration of the top gate region 8A may be the same as the impurity concentration of the bottom gate region 7A.

Referring to FIG. 10, a thickness (depth of impurity diffusion) of the first bottom gate region 71A at the source region 10A side and a thickness (depth of impurity diffusion) of the second bottom gate region 72A at the drain region 11A side differ. The thickness of the second bottom gate region 72A is thinner than the thickness of the first bottom gate region 71A. Thereby, an interval D1 in the thickness direction between the top gate region 8A and the first bottom gate region 71A is smaller than an interval D2 in the thickness direction between the top gate region 8A and the second bottom gate region 72A. The interval D1 is preferably not less than ⅕ and not more than ⅘ of the interval D2. In this preferred embodiment, the interval D1 is approximately ½ of the interval D2.

The first bottom gate region 71A may integrally include a first gate facing portion 73A and a first gate lead-out portion 74A. The first gate facing portion 73A may be a region that faces a region of the top gate region 8A at the source region 10A side in the thickness direction of the epitaxial layer 42A. The first gate lead-out portion 74A is led out to the source region 10A side in a direction along the element principal surface 43A from the first gate facing portion 73A. The first gate lead-out portion 74A does not face the top gate region 8A in the thickness direction of the epitaxial layer 42A and may thus be referred to as a first gate non-facing portion.

The second bottom gate region 72A may integrally include a second gate facing portion 75A and a second gate lead-out portion 76A. The second gate facing portion 75A may be a region that faces a region of the top gate region 8A at the drain region 11A side in the thickness direction of the epitaxial layer 42A. The second gate lead-out portion 76A is led out to the drain region 11A side in the direction along the element principal surface 43A from the second gate facing portion 75A. The second gate lead-out portion 76A does not face the top gate region 8A in the thickness direction of the epitaxial layer 42A and may thus be referred to as a second gate non-facing portion.

In this preferred embodiment, the gate contact region 9A is of an n⁺ type and has a higher impurity concentration than the bottom gate region 7A and the top gate region 8A. As shown in FIG. 9 and FIG. 10, the gate contact region 9A is formed in a surface layer portion of the element principal surface 43A of the epitaxial layer 42A.

The gate contact region 9A integrally includes a first contact portion 91A that is electrically connected to the bottom gate region 7A and a second contact portion 92A that is electrically connected to the top gate region 8A.

Referring to FIG. 9, the first contact portion 91A is formed in an annular shape along a peripheral edge portion of the bottom gate region 7A. In this preferred embodiment, the first contact portion 91A is formed in a quadrilateral annular shape in plan view that includes a pair of first rectilinear portions 911A that face each other and a pair of second rectilinear portions 912A that face each other. The first rectilinear portions 911A and the second rectilinear portions 912A may be orthogonal to each other.

Referring to FIG. 10, a gate intermediate region 77A is formed between the first contact portion 91A and a peripheral edge portion (the first gate lead-out portion 74A and the second gate lead-out portion 76A) of the bottom gate region 7A. In this preferred embodiment, the gate intermediate region 77A is of the n type and has a lower impurity concentration than the bottom gate region 7A and the top gate region 8A.

The gate intermediate region 77A includes a first gate intermediate region 78A that is formed between the first contact portion 91A and the first gate lead-out portion 74A and a second gate intermediate region 79A that is formed between the first contact portion 91A and the second gate lead-out portion 76A. The second gate intermediate region 79A includes a lower region 79Aa and an upper region 79Ab. A length of the second gate intermediate region 79A along the thickness direction of the epitaxial layer 42A is longer than a length of the first gate intermediate region 78A along the thickness direction of the epitaxial layer 42A.

The first gate intermediate region 78A is physically and electrically connected to both the first contact portion 91A and the first gate lead-out portion 74A and is sandwiched from above and below by the first contact portion 91A and the first gate lead-out portion 74A. The second gate intermediate region 79A is physically and electrically connected to both the first contact portion 91A and the second gate lead-out portion 76A and is sandwiched from above and below by the first contact portion 91A and the second gate lead-out portion 76A. The first contact portion 91A (gate contact region 9A) is thereby electrically connected to the bottom gate region 7A via the gate intermediate regions 78A and 79A.

Also, with reference to FIG. 9, the gate intermediate region 77A is formed in an annular shape (quadrilateral annular shape in this preferred embodiment) along the first contact portion 91A. The gate intermediate region 77A has a wider width than the first contact portion 91A in plan view. Thereby, the gate intermediate region 77A has a lead-out portion 80A led out from both sides in a width direction of the first contact portion 91A. In this preferred embodiment, the gate intermediate region 77A of annular shape has the lead-out portion 80A at both an inner side and an outer side of the annulus.

With reference to FIG. 9, the second contact portion 92A is formed across a plurality of locations of the first contact portion 91A such as to segment the bottom gate region 7A. In this preferred embodiment, the second contact portion 92A is formed in a rectilinear shape that connects the pair of first rectilinear portions 911A to each other. The second contact portion 92A is formed on the top gate region 8A and is of the rectilinear shape along the top gate region 8A. Therefore, in plan view, the first bottom gate region 71A and the second bottom gate region 72A may be divided from each other in a lateral direction by the second contact portion 92A. In this preferred embodiment, the second contact portion 92A is present at a position directly above a boundary between the first bottom gate region 71A and the second bottom gate region 72A.

Here, the boundary between the first bottom gate region 71A and the second bottom gate region 72A may, in plan view, be disposed further to the drain region 11A side than a width center of the top gate region 8A (width center of the second contact portion 92A) within a range from the width center of the top gate region 8A to an end of the top gate region 8A at the drain region 11A side. Also, the boundary between the first bottom gate region 71A and the second bottom gate region 72A may, in plan view, be disposed further to the source region 10A side than the width center of the top gate region 8A (width center of the second contact portion 92A) within a range from the width center of the top gate region 8A to an end of the top gate region 8A at the source region 10A side.

Here, the top gate region 8A has a wider width than the second contact portion 92A in plan view. Thereby, the top gate region 8A has a lead-out portion 81A led out from both sides in a width direction of the second contact portion 92A. The second contact portion 92A is physically and electrically connected to the top gate region 8A. Thereby, the gate contact region 9A including the first contact portion 91A and the second contact portion 92A is electrically connected in common to the bottom gate region 7A and the top gate region 8A.

In this preferred embodiment, the source region 10A is of the p⁺ type and has a higher impurity concentration than the channel region 12A. As shown in FIG. 9 and FIG. 10, the source region 10A is formed in a surface layer portion of the element principal surface 43A of the epitaxial layer 42A. Referring to FIG. 9, the source region 10A is formed on the first bottom gate region 71A and is separated from the top gate region 8A in the direction along the element principal surface 43A.

The source region 10A is formed near a central portion of the first bottom gate region 71A in a direction orthogonal to the top gate region 8A (right-left direction of the sheet of FIG. 10). The source region 10A may instead be formed to a side closer to the top gate region 8A or a side further from the top gate region 8A than the central portion of the first bottom gate region 71A in the direction orthogonal to the top gate region 8A.

In this preferred embodiment, the drain region 11A is of the p⁺ type and has a higher impurity concentration than the channel region 12A. As shown in FIG. 9 and FIG. 10, the drain region 11A is formed in a surface layer portion of the element principal surface 43A of the epitaxial layer 42A. Referring to FIG. 9, the drain region 11A is formed on the second bottom gate region 72A and is separated to an opposite side of the source region 10A from the top gate region 8A in the direction along the element principal surface 43A.

The drain region 11A is formed near a central portion of the second bottom gate region 72A in the direction orthogonal to the top gate region 8A. The drain region 11A may instead be formed to a side closer to the top gate region 8A or a side further from the top gate region 8A than the central portion of the second bottom gate region 72A in the direction orthogonal to the top gate region 8A.

Referring to FIG. 9, the channel region 12A is formed between the source region 10A and the drain region 11A in the direction along the element principal surface 43A. For example, the channel region 12A may be formed at a substantially central portion between the source region 10A and the drain region 11A. Referring to FIG. 10, the channel region 12A is formed between the bottom gate region 7A and the top gate region 8A in the thickness direction of the epitaxial layer 42A. In this preferred embodiment, the channel region 12A is of the p type. A width Wc of the channel region 12A in the thickness direction of the epitaxial layer 42A may, for example, be not less than 0.5 μm and not more than 2 μm.

In this preferred embodiment, the channel region 12A contacts the top gate region 8A and forms an interface with the top gate region 8A. On the other hand, the channel region 12A is separated from the bottom gate region 7A. That is, a portion of the inner epitaxial region 46A of the p⁻ type is interposed between the channel region 12A and the bottom gate region 7A. Thereby, an npn structure with which portions of the channel region 12A of the p type and the inner epitaxial region 46A of the p⁻ type are sandwiched from both upper and lower sides by the n type gate regions 7A and 8A is formed. This npn structure forms a p-channel junction field effect transistor (JFET 3A).

Here, the channel region 12A may contact both the bottom gate region 7A and the top gate region 8A. Also, the channel region 12A may contact the bottom gate region 7A and be separated from the top gate region 8A.

In this preferred embodiment, the channel region 12A may include a channel portion 121A and a channel peripheral portion 122A. The channel portion 121A is a portion that is sandwiched between the top gate region 8A and the inner epitaxial region 46A below the top gate region 8A. The channel peripheral portion 122A is formed further outward than the top gate region 8A in plan view and may be a portion that surrounds both the top gate region 8A and the channel portion 121A.

As with the JFET 3 described above, the gate current can be reduced and the drain current can be increased with the JFET 3A as well.

[Method for Manufacturing the p-Channel JFET 3A]

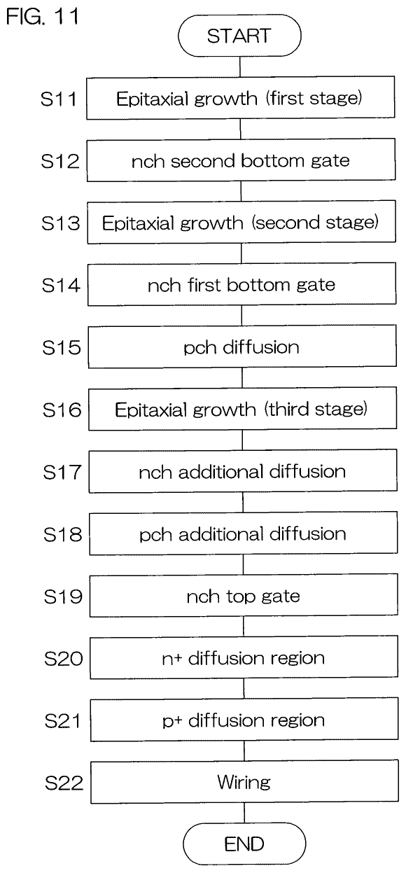

FIG. 11 is a flowchart showing a portion of a manufacturing process of the JFET 3A. Next, an example of the manufacturing process of the JFET 3A shall be described with reference to FIG. 11.

To manufacture the JFET 3A, first, the base substrate 41 of the p⁻ type is prepared. Next, an impurity of the p type is implanted selectively into a front surface of the base substrate 41. Then while adding the impurity of the p type, the silicon of the base substrate 41 is grown epitaxially (step S11). The semiconductor substrate 4A that includes the base substrate 41 of the p⁻ type and the epitaxial layer 42A (first stage portion) of the p⁻ type is thereby formed.

The impurity of the p type that is implanted into the base substrate 41 during the epitaxial growth of the base substrate 41 diffuses in a growth direction of the epitaxial layer 42A. The boundary portion between the base substrate 41 and the epitaxial layer 42A and the low isolation region 52 of the p⁻ type are thereby formed.

Next, an ion implantation mask having an opening selectively in a region in which the second bottom gate region 72A of the n type is to be formed is formed on the epitaxial layer 42A. An impurity of the n type is then implanted into the epitaxial layer 42A via the ion implantation mask. The second bottom gate region 72A of the n type is thereby formed (step S12).

Next, the silicon of the base substrate 41 is grown epitaxially further while adding the impurity of the p type (step S13). A second stage portion of the epitaxial layer 42A of the p⁻ type is thereby formed.

Next, an ion implantation mask having openings selectively in regions in which the first bottom gate region 71A of the n type and the second gate intermediate region 79A are to be formed is formed on the epitaxial layer 42A. The impurity of the n type is then implanted into the epitaxial layer 42A via the ion implantation mask. Thereby, the first bottom gate region 71A of the n type is formed and the lower region 79Aa of the second gate intermediate region 79A is formed (step S14).

Next, an ion implantation mask having an opening selectively in a region in which the well region 51 of the p type is to be formed is formed on the epitaxial layer 42A. The impurity of the p type is then implanted into the the element isolation portion 5 (element isolation well) constituted of the two-layer structure of the well region 51 (the portion lower than the virtual boundary 54 of FIG. 10) of the p type and the low isolation region 52 of the p-type is formed (step S15).

Next, the silicon of the base substrate 41 is grown epitaxially further while adding the impurity of the p type (step S16). A third stage portion of the epitaxial layer 42A of the p⁻ type is thereby formed.

Next, an ion implantation mask having an opening selectively in a region in which the gate intermediate region 77A (78A and 79A) of the n type is to be formed is formed on the epitaxial layer 42A. The impurity of the n type is then implanted into the epitaxial layer 42A via the ion implantation mask. Thereby, the first gate intermediate region 78A of the n type and the upper region 79Ab of the second gate intermediate region 79A are formed. Thereby, the gate intermediate region 77A constituted of the first gate intermediate region 78A and the second gate intermediate region 79A is formed (step S17).

Next, an ion implantation mask having an opening selectively in a region in which the well region 51 of the p type is to be formed is formed on the epitaxial layer 42A. The impurity of the p type is then implanted into the the well region 51 (the portion higher than the virtual boundary 54 of FIG. 10) of the p type is formed.

Next, an ion implantation mask having an opening selectively in a region in which the channel region 12A of the p type is to be formed is formed on the epitaxial layer 42A. The impurity of the p type is then implanted into the epitaxial layer 42A via the ion implantation mask. Thereby, the channel region 12A of the p type is formed (step S18).

Next, an ion implantation mask having an opening selectively in a region in which the top gate region 8A of the n type is to be formed is formed on the epitaxial layer 42A. The impurity of the n type is then implanted into the epitaxial layer 42A via the ion implantation mask. Thereby, the top gate region 8A of the n type is formed (step S19).

Next, an ion implantation mask having an opening selectively in a region in which the gate contact region 9A of the n⁺ type is to be formed is formed on the epitaxial layer 42A. The impurity of the n type is then implanted into the epitaxial layer 42A via the ion implantation mask. Thereby, the gate contact region 9A of the n⁺ type is formed (step S20).

Next, an ion implantation mask having openings selectively in regions in which the source region 10A of the p⁺ type and the drain region 11A of the p⁺ type are to be formed is formed on the epitaxial layer 42A. The impurity of the p type is then implanted into the epitaxial layer 42A via the ion implantation mask. Thereby, the source region 10A of the p⁺ type and the drain region 11A of the p⁺ type are formed (step S21).

Next, by a forming step of the wirings 15 to 18 (step S22), etc., being performed, the JFET 3A described above is obtained.

Here, the manufacturing process of the JFET 3A described using FIG. 11 is one example and the JFET 3A may be manufactured by another manufacturing process instead.

Although preferred embodiments of the present disclosure have been described above, the present disclosure can be implemented in yet other preferred embodiments.

For example, in each of the preferred embodiments described above, a structure in which the conductivity types of the respective semiconductor portions are inverted may be adopted. That is, a p type portion may be of an n type and an n type portion may be of a p type.

Thus, the preferred embodiments of the present disclosure in all respects are illustrative and not to be interpreted to be restrictive and are intended to include modifications in all respects.

The following appended features can be extracted from the descriptions in this Description and the drawings.

### [Appendix 1-1]

A semiconductor device (1) including
a semiconductor layer (42, 42A) having a first surface (43, 43A),
a bottom gate region (7, 7A) of a first conductivity type that is formed in the semiconductor layer (42, 42A),
a top gate region (8, 8A) of the first conductivity type that is formed in a surface layer portion of the first surface (43, 43A) of the semiconductor layer (42, 42A) and faces the bottom gate region (7, 7A) in a thickness direction of the semiconductor layer (42, 42A),
a source region (10, 10A) of a second conductivity type that is formed in a surface layer portion of the first surface (43, 43A) of the semiconductor layer (42, 42A) and is separated from the top gate region (8, 8A) in a direction along the first surface (43, 43A),
a drain region (11, 11A) of the second conductivity type that is formed in a surface layer portion of the first surface (43, 43A) of the semiconductor layer (42, 42A) and is separated to an opposite side of the source region (10, 10A) from the top gate region (8, 8A) in the direction along the first surface (43, 43A), and
a channel region (12, 12A) of the second conductivity type that is formed between the source region (10, 10A) and the drain region (11, 11A) in a direction along the first surface (43, 43A) and is formed between the bottom gate region (7, 7A) and the top gate region (8, 8A) in the thickness direction of the semiconductor layer (42, 42A), and
where the bottom gate region (7, 7A) includes a first bottom gate region (71, 71A) at the source region side and a second bottom gate region (72, 72A) at the drain region side and
an interval (D2) in the thickness direction between the second bottom gate region (72, 72A) and the top gate region (8, 8A) is greater than an interval (D1) in the thickness direction between the first bottom gate region (71, 71A) and the top gate region (8, 8A).

### [Appendix 1-2]

The semiconductor device (1) according to Appendix 1-1, where the first bottom gate region (71, 71A) integrally includes a first gate facing portion (73, 73A) that faces the top gate region (8, 8A) and a first gate lead-out portion (74, 74A) that is led out from the first gate facing portion (73, 73A) to a position below the source region (10, 10A) and
the second bottom gate region (72, 72A) integrally includes a second gate facing portion (75, 75A) that faces the top gate region (8, 8A) and a second gate lead-out portion (76, 76A) that is led out from the second gate facing portion (75, 75A) to a position below the drain region (11, 11A).

### [Appendix 1-3]

The semiconductor device (1) according to Appendix 1-1 or Appendix 1-2, including an insulating layer (13) that is formed on the first surface (43, 43A) of the semiconductor layer (42, 42A) and has openings (142, 143) that expose the source region (10, 10A) and the drain region (11, 11A).

### [Appendix 1-4]

The semiconductor device (1) according to any one of Appendix 1-1 to Appendix 1-3, including a gate contact region (9, 9A) that is formed in a surface layer portion of the first surface (43, 43A) of the semiconductor layer (42, 42A) and is electrically connected in common to the bottom gate region (7, 7A) and the top gate region (8, 8A) and
where the bottom gate region (7, 7A) is formed in an island shape in plan view and
the gate contact region (9, 9A) in plan view integrally includes a first contact portion (91, 91A) that is formed in an annular shape along a peripheral edge portion of the bottom gate region (7, 7A) and is electrically connected to the bottom gate region (7, 7A) and a second contact portion (92, 92A) that is formed across a plurality of locations of the first contact portion (91, 91A) such as to segment the bottom gate region (7, 7A) and is electrically connected to the top gate region (8, 8A).

### [Appendix 1-5]

The semiconductor device (1) according to Appendix 1-4, where the bottom gate region (7, 7A) includes the first bottom gate region (71, 71A) and the second bottom gate region (72, 72A) that are divided by the second contact portion (92, 92A) in plan view,
the source region (10, 10A) is formed on the first bottom gate region (71, 71A), and
the drain region (11, 11A) is formed on the second bottom gate region (72, 72A).

### [Appendix 1-6]

The semiconductor device (1) according to Appendix 1-4 or Appendix 1-5, where the first contact portion (91, 91A) is formed in a quadrilateral annular shape in plan view that includes a pair of first rectilinear portions (911, 911A) that face each other and a pair of second rectilinear portions (912, 912A) that face each other and
the second contact portion (92, 92A) is formed in a rectilinear shape that connects the pair of first rectilinear portions (911, 911A) to each other.

### [Appendix 1-7]

The semiconductor device (1) according to any one of Appendix 1-4 to Appendix 1-6, including a gate intermediate region (77, 77A) that is formed to be sandwiched between the peripheral edge portion of the bottom gate region (7, 7A) and the first contact portion (91, 91A) and has an impurity concentration lower than an impurity concentration of the bottom gate region (7, 7A) and an impurity concentration of the gate contact region (9, 9A).

### [Appendix 1-8]

The semiconductor device (1) according to Appendix 1-7, where the gate intermediate region (77, 77A) includes
a first gate intermediate region (78, 78A) that is formed to be sandwiched between the first bottom gate region (71, 71A) and the first contact portion (91, 91A) and a second gate intermediate region (79, 79A) that is formed to be sandwiched between the second bottom gate region (72, 72A) and the first contact portion (91, 91A).

### [Appendix 1-9]

The semiconductor device (1) according to Appendix 1-8, where a length of the second gate intermediate region (79, 79A) along the thickness direction of the semiconductor layer (42, 42A) is longer than a length of the first gate intermediate region (78, 78A) along the thickness direction of the semiconductor layer (42, 42A).

### [Appendix 1-10]

The semiconductor device (1) according to Appendix 1-1 or Appendix 1-2, including an insulating layer (13) that is formed on the first surface (43, 43A) of the semiconductor layer (42, 42A) and has a gate opening (141), and
a gate contact region (9, 9A) that is formed in a surface layer portion of the first surface (43, 43A) of the semiconductor layer (42, 42A), is electrically connected to the top gate region (8, 8A), and is exposed from the gate opening (141).

### [Appendix 1-11]

The semiconductor device (1) according to any one of Appendix 1-1 to Appendix 1-10, where a width of the channel region (12, 12A) in the thickness direction of the semiconductor layer (42, 42A) is not less than 0.5 μm and not more than 2 μm.

### [Appendix 1-12]

The semiconductor device (1) according to any one of Appendix 1-1 to Appendix 1-11, where the interval (D1) in the thickness direction between the first bottom gate region (71, 71A) and the top gate region (8, 8A) is not less than ⅕ and not more than ⅘ of the interval (D2) in the thickness direction between the second bottom gate region (72, 72A) and the top gate region (8, 8A).

What is claimed is:

1. A semiconductor device comprising:
a semiconductor layer having a first surface;
a bottom gate region of a first conductivity type that is formed in the semiconductor layer;
a top gate region of the first conductivity type that is formed in a surface layer portion of the first surface of the semiconductor layer and faces the bottom gate region in a thickness direction of the semiconductor layer;
a source region of a second conductivity type that is formed in a surface layer portion of the first surface of the semiconductor layer and is separated from the top gate region in a direction along the first surface;
a drain region of the second conductivity type that is formed in a surface layer portion of the first surface of the semiconductor layer and is separated to an opposite side of the source region from the top gate region in the direction along the first surface; and
a channel region of the second conductivity type that is formed between the source region and the drain region in a direction along the first surface and is formed between the bottom gate region and the top gate region in the thickness direction of the semiconductor layer; and
wherein the bottom gate region includes a first bottom gate region at the source region side and a second bottom gate region at the drain region side and
an interval in the thickness direction between the second bottom gate region and the top gate region is greater than an interval in the thickness direction between the first bottom gate region and the top gate region.

2. The semiconductor device according to claim 1, wherein the first bottom gate region integrally includes a first gate facing portion that faces the top gate region and a first gate lead-out portion that is led out from the first gate facing portion to a position below the source region and
the second bottom gate region integrally includes a second gate facing portion that faces the top gate region and a second gate lead-out portion that is led out from the second gate facing portion to a position below the drain region.

3. The semiconductor device according to claim 1, comprising: an insulating layer that is formed on the first surface of the semiconductor layer and has openings that expose the source region and the drain region.

4. The semiconductor device according to claim 1, comprising: a gate contact region that is formed in a surface layer portion of the first surface of the semiconductor layer and is electrically connected in common to the bottom gate region and the top gate region; and
wherein the bottom gate region is formed in an island shape in plan view and
the gate contact region in plan view integrally includes a first contact portion that is formed in an annular shape along a peripheral edge portion of the bottom gate region and is electrically connected to the bottom gate region and a second contact portion that is formed across a plurality of locations of the first contact portion such as to segment the bottom gate region and is electrically connected to the top gate region.

5. The semiconductor device according to claim 4, wherein the bottom gate region includes the first bottom gate region and the second bottom gate region that are divided by the second contact portion in plan view,
the source region is formed on the first bottom gate region, and
the drain region is formed on the second bottom gate region.

6. The semiconductor device according to claim 4, wherein the first contact portion is formed in a quadrilateral annular shape in plan view that includes a pair of first rectilinear portions that face each other and a pair of second rectilinear portions that face each other and
the second contact portion is formed in a rectilinear shape that connects the pair of first rectilinear portions to each other.

7. The semiconductor device according to claim 4, comprising: a gate intermediate region that is formed to be sandwiched between the peripheral edge portion of the bottom gate region and the first contact portion and has an impurity concentration lower than an impurity concentration of the bottom gate region and an impurity concentration of the gate contact region.

8. The semiconductor device according to claim 7, wherein the gate intermediate region includes
a first gate intermediate region that is formed to be sandwiched between the first bottom gate region and the first contact portion and
a second gate intermediate region that is formed to be sandwiched between the second bottom gate region and the first contact portion.

9. The semiconductor device according to claim 8, wherein a length of the second gate intermediate region along the thickness direction of the semiconductor layer is longer than a length of the first gate intermediate region along the thickness direction of the semiconductor layer.

10. The semiconductor device according to claim 1, comprising: an insulating layer that is formed on the first surface of the semiconductor layer and has a gate opening; and
a gate contact region that is formed in a surface layer portion of the first surface of the semiconductor layer, is electrically connected to the top gate region, and is exposed from the gate opening.

11. The semiconductor device according to claim 1, wherein a width of the channel region in the thickness direction of the semiconductor layer is not less than 0.5 μm and not more than 2 μm.

12. The semiconductor device according to claim 1, wherein the interval in the thickness direction between the first bottom gate region and the top gate region is not less than ⅕ and not more than ⅘ of the interval in the thickness direction between the second bottom gate region and the top gate region.
